(19) United States
(12) Patent Application Publication
(10) Pub. No.: US 2007/0093035 A1
(43) Pub. Date: Apr. 26, 2007

(54) Circuit board materials with improved bond to conductive metals and methods of the manufacture thereof

(76) Inventors: Robert C. Daigle, Amston, CT (US); Amit Das, State College, PA (US); Sankar K. Paul, Branford, CT (US); Dirk M. Baars, South Windsor, CT (US); Allen F. Horn III, Pomfret Center, CT (US)

Correspondence Address: CANTOR COLBURN, LLP, 55 GRIFFIN ROAD SOUTH, BLOOMFIELD, CT, 06002, US

(21) Appl. No.: 11/583,999

(22) Filed: Oct. 19, 2006

Related U.S. Application Data
(60) Provisional application No. 60/728,101, filed on Oct. 19, 2005.

(51) Int. Cl. H01L 21/30; H01L 21/46

(52) U.S. Cl. 438/455; 438/458

(57) ABSTRACT

Use of a roughened dielectric layer between a dielectric substrate and a conductive layer, which allows increased adhesion between layers without the conductor loss associated with roughened conductor layers, as well as improved accuracy in etching. The method is widely applicable to a variety of dielectric substrate and conductive layer constructions, and can be readily tuned to provide the desired level of adhesion and other advantageous properties.

### CROSS-REFERENCE TO RELATED APPLICATION

The application claims the benefit of U.S. Provisional Application Ser. No. 60/728,101, filed Oct. 19, 2005, which is incorporated by reference herein it its entirety.

### BACKGROUND

This invention relates to methods for improving the bond between a conductive metal surface and a circuit board substrate, in particular a copper foil and a low loss circuit board substrate.

Circuit board materials are well known in the art, generally comprising an insulating dielectric substrate adhered to a conductive metal layer. The conductive metal layer is usually a copper foil, due to its high electrical conductivity and relatively low cost.

For many years, the standard approach to achieving an acceptable bond between the copper foil and the insulating dielectric substrate has been to increase the roughness of the foil and additionally to plate high surface area conducting nodules onto the foil to provide a higher degree of mechanical interlocking between the resin in of dielectric substrate and the copper foil.

This mechanical roughening has several drawbacks. As described in detail by Brist et al., in “Non-classical conductor losses due to copper foil roughness and treatment,” p. 26, Circuitree, can 2005 and by Ogawa et al., in “Profile-free foil for high-density packaging substrates and high-frequency applications,” p. 457, Proceedings of the 2005 Electronic Components and Technology Conference, IEEE, a rough conductor surface can result in a substantial increase in conductor loss at high frequencies. In fact, rough conductor surfaces can cause up to twice the conductor loss of a smooth surface. Rough conductor surfaces also limit accurate circuit fabrication, most notably the accurate etching of fine lines and spaces.

A number of efforts have been made to improve the bond between the substrate material and the copper foil. U.S. Pat. No. 6,419,811 to Manabe et al. describes a roughening and subsequent treatment process. However, this process results in a maximum peak-to-valley roughness, Rz, of the copper foil of 7.5 micrometers to 9 micrometers. This roughness would result in both increased high frequency conductor loss and etching difficulties.

Use of bonding layers has also been described. U.S. Pat. No. 5,904,797 to Kwei discloses using chromium (III) methacrylate/polyvinyl alcohol solutions to improve bonding between thermoset resins and metal surfaces. While useful for some thermoset resins, the solutions are not effective with many resins having low dielectric constant and low polarity, for example polybutadiene and polyisoprene thermosetting resin systems and fluoropolymers such as polytetrafluoroethylene (PTFE). U.S. Patent Application 2004/0060729 to Knadle and Sargent describe plating a smooth copper foil with a conductive polymer such as polypyrrole, polyaniline, or polythiophene for improving bond to a circuit substrate. The bond improvement is small, and it is believed that these conductive polymers would not promote adhesion to the polybutadiene or polyisoprene thermoset resins or to fluoropolymers.

There accordingly remains a need in the art for methods to improve the adhesion of a smooth conductive layer to an electrically insulating substrate for the purpose of building a high speed or fine line multilayer circuit board.

### SUMMARY

A process for adhering a conductive layer to a dielectric substrate in a circuit material comprises imparting non-conductive roughness to a surface of the conductive layer; and bonding the roughened surface of the conductive layer under heat and pressure to the dielectric substrate. The non-conductive roughness enhances the bond between the conductive layer and the dielectric by increasing the surface area in contact with the substrate, thereby providing a degree of mechanical interlocking. Unlike the conventional plated roughness of the prior art, the non-conductive roughness does not cause an increase in the conductor loss at high frequencies since it carries no current. Furthermore, since only the smooth conductive material is etched away during circuit processing, the non-conductive roughness does not contribute to the degradation of etch definition.

In one embodiment the non-conductive roughness is imparted by adhering dielectric (i.e., electrically insulating) particles to the surface, for example mineral fillers, ceramic fillers, or polymeric particles having a median particle size of greater than 1 micrometer.

The dielectric particles can be adhered to the smooth copper foil by any of a number of methods. For example, use of a thin layer of a high temperature thermoset adhesive layer, such as epoxy or polyimide resin, or certain silicone thermoset resins. Thin films of some high temperature thermoplastics can also exhibit sufficient bond to both the copper foil and the dielectric particles. Alkoxy silane compounds that react both with the copper oxide formed on the surface of copper foil and the surface hydroxyl groups found on many mineral and ceramic fillers can also be used. Another method for bonding the dielectric particles comprises heating the conductive metal in a reactive atmosphere to form a thin layer of a “eutectic melt” that can wet both the metal foil and the ceramic substrate and form a bond. One description of this process is set forth in U.S. Pat. No. 3,993,411 to Babcock et al.

Alternatively, non-conductive roughness can be patterned onto a thermoset or thermoplastic polymeric layer that is adhered to the smooth copper foil. Patterning can be accomplished by a number of different methods, for example printing, gravure printing/coating, chemical etching, mechanical embossing, or laser machining.

In still another embodiment, a non-conductive roughness is imparted to the conductive surface by foaming a thermoset or thermoplastic polymeric layer onto the smooth conductive layer. In this embodiment the pores of the foam are filled by the dielectric substrate resin during lamination of the foil to the circuit substrate. The foamed polymeric layer can be achieved by mechanical frothing, chemical blowing agents, or fugitive fillers that are subsequently removed by chemical treatment, solvents, or heat.

The above discussed and other features and advantages of the present invention will be appreciated and understood by those skilled in the art from the following detailed description.

### BRIEF DESCRIPTION OF THE DRAWINGS

Referring now to the exemplary drawings, wherein like elements are numbered alike:

FIG. 1 plot of the attenuation factor, {1+2/πtan−1 (1.4(Δ/δs)2), versus frequency with conductor roughness as a parameter.

FIG. 2 is a cross-sectional view of a circuit material comprising non-conductive roughness imparted by dielectric particles;

FIG. 3 is a cross-sectional view of a circuit material comprising non-conductive roughness imparted by a porous foam; and

FIG. 4 is a cross-sectional view of a circuit material comprising non-conductive roughness imparted by a roughened polymer layer.

### DETAILED DESCRIPTION

Use of a roughened dielectric layer between a dielectric substrate and a conductive layer allows increased adhesion between layers without the conductor loss associated with roughened conductor layers, as well as improved accuracy in etching. The method is widely applicable to a variety of dielectric substrate and conductive layer constructions, and can be readily tuned to provide the desired level of adhesion and other advantageous properties.

Suitable dielectric substrates included for example, thermosetting and thermoplastic substrates based on polybutadiene and polyisoprene, polyolefins, PTFE, epoxies, polyimides, cyanate esters, polyesters, BT, poly(arylene ether), and the like. The substrates can be filled or unfilled, and further comprise optional woven or nonwoven reinforcement.

Useful conductive layers for the formation of circuit materials, circuits, and multi-layer circuits include stainless steel, copper, aluminum, zinc, iron, transition metals, and alloys comprising at least one of the foregoing. The conductive layer has a thickness of about 3 micrometers to about 200 micrometers, with about 9 micrometers to about 180 micrometers especially useful. When two or more conductive layers are present, the thickness of the two layers can be the same or different.

Copper foil is widely used as the conductive metal in circuit board materials. The copper foil can be made either by electro deposition (ED) on a rotating stainless steel drum from a copper sulfate bath, or by rolling (flattening) of solid copper bars. In the case of the ED foil, if the copper foil is to be used as cladding on an organic circuit board substrate, an initial roughness of the base foil is created in the foil plating process on the “bath side” (or matte side) of the foil. Additional roughness is created in a secondary plating step. In the case of the rolled foil, only a secondary plating step contributes additional roughness to the initially smooth and shiny foil.

The roughness of a surface such as the surface of a copper foil is generally characterized by contact profilometry or optical interferometry. Most foil manufacturers have historically measured roughness with a contact profilometer. Most of the values cited by the inventors of the present invention were measured using a Veeco Instruments WYCO Optical Profiler, using the method of white light interferometry. Since the roughness can exist on several different scales and will consist of many peaks and valleys with varying distances from a fixed reference plane, there are many different ways to numerically characterize the surface roughness. Two frequently reported quantities are the root mean squared (rms) roughness value, Rq, and the peak-to-valley roughness, Rz, with both reported in dimensions of length.

Conventional ED copper foil made for the circuit industry has had treated side Rz values of 7 to 20 micrometers (corresponding to Rq values of about 1.2 to 4 micrometers) when measured by the WYCO Optical Profiler. Contact profilometers tend to yield lower values due to the stylus deforming the copper treatment as the measurement is made. The treated side of rolled copper foil conventionally exhibits Rz values of 3.5 to 5.5 micrometers (corresponding to Rq values of 0.45 to 0.9 micrometers). According to Ogawa, et al. supra, the lower profile ED foils currently exhibit Rz values of 2 to 3 micrometers. Using the WYCO Optical Profiler, the shiny side of rolled foil has been found to exhibit an Rz value of about 0.7 micrometers and a corresponding Rq of about 0.1 micrometers.

In contrast, in the present invention, a smooth conductive surface is desired in order to improve high frequency performance. Thus in one embodiment, the conductive surface is a smooth as possible, for example having an rms roughness of about 0.4 micrometers or less, preferably about 0.3 micrometers or less, more preferably about 0.2 micrometers or less, or even more preferably about 0.1 micrometer or even less.

Pozar, in Microwave Engineering, 2nd Edition, John Wiley & Sons, Inc., New York (1998) presents on page 98 a quasi-empirical equation describing the effect of roughness on conductor loss: [symbol]
_{c}=α_{c}{1+2/π⁻¹ (1.4(Δ/δs)²)
where

[symbol] _{c} is the conductor loss corrected for roughness,

α_{c} is the smooth conductor loss,

Δ is the rms roughness of conductor, and

When Δ/δs is small, the arctangent value is small and the effect of roughness on conductor loss is minimal. This occurs when the conductor is relatively smooth, or when the frequency is comparatively low, resulting in a large skin depth, δs.

As Δ/δs approaches 1, the value of the arctangent becomes significant and when Δ/δs becomes large, the value approaches π/2. Thus, when the rms roughness is approximately ⅓ the skin depth, the roughness increases conductor loss by about 10%. Thus, when the rms roughness is twice the skin depth, the conductor loss is increased by about 90%. According to this equation, the maximum effect of conductor roughness is to double the loss value over that of a smooth conductor.

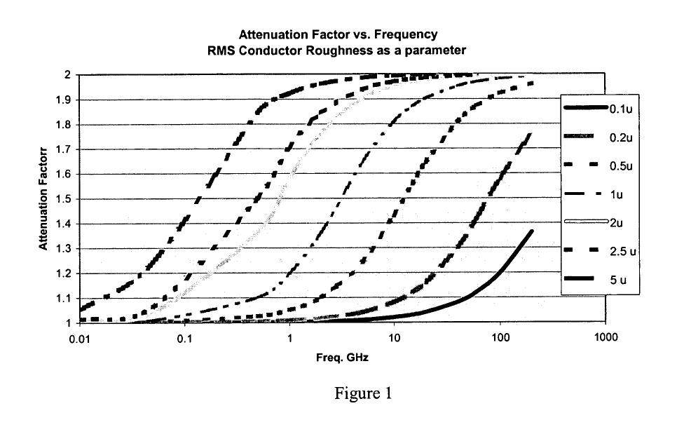

A plot of the attenuation factor, {1+2/πtan−1 (1.4(Δ/δs)2), versus frequency with conductor roughness as a parameter is shown in FIG. 1. It can be seen from the figure that the rms roughness of the conductor must be less than about 0.5 micrometers to avoid excessive conductor loss in the 1 GHz to 10 GHz frequency range, and less than 0.2 micrometers to avoid excessive conductor loss in the 10 to 100 GHz range. Thus, one embodiment of the present invention, the rms roughness of the conductive layer is less than 0.5 micrometers, and more preferably less than 0.2 micrometers.

In order to retain the mechanical adhesion provided by surface roughening, non-conductive roughness is imparted to the surface of the copper foil using an insulating material. The non-conductive roughness is imparted to the preferably smooth conductive surface to a degree effective to provide enhanced mechanical adhesion, and will thus depend on the type of non-conductive roughening, conductive surface, and dielectric material. In one embodiment, rms roughness of the non-conductive surface is about 0.5 micrometers or greater, about 1.0 micrometers or greater, about 2 micrometers or greater, about 3 micrometers or greater, or about 4 micrometers or greater, up to about 10 micrometers.

In one embodiment, non-conductive roughness is imparted to the surface of a conductive layer by adhering dielectric particles to the surface. The dielectric particles can be, for example, inorganic particles such as fused amorphous silica, zirconia, nepheline syenite, glass, quartz, alumina, titanium dioxide, magnesium oxide, aluminum nitride, clay, mica and other natural and synthetic aluminosilicates; or dielectric polymer particles such as epoxies, polyimides, silicones, polyamides, polyarylene ethers, cyanurates, polybenzoxazines, polybenzoxazoles, polybenzimidizoles, polyarylates, polyesters, polycarbonates, polyethers, polyurethanes, polysulfones, and copolymers and mixtures thereof. Where copper is used as the conduction layer, fused amorphous silica can be preferred due to its low dielectric constant value of 3.8, and the presence of surface hydroxyl groups that can be used to facilitate bonding to a variety of coupling agents.

The particles can be of any geometry effective to provide mechanical bonding of the organic dielectric substrate, for example spherical, rod-like, whisker, or irregularly shaped. Acicular (needle-like) materials such as wollastinite or calcium silicate can also offer unique advantages in increasing the mechanical bond between non-conductive roughened surface and the organic circuit substrate, due to the high aspect ratio of the particles. A combination of shapes can also be used. In one embodiment, nanosize particles are agglomerated to form larger particles, preferably larger particles of defined shapes, for example fishhook, “T,” “S,” or other geometry effective to enhance mechanical bonding.

Since the purpose of the particles is to impart mechanical roughness to the surface, the size of the particles or agglomerates is adjusted to provide the desired surface roughness and surface configuration. The median longest dimension of the particles can be larger than about 1 micrometer, more specifically larger than about 2.5 micrometers, or even larger than about 3.5 micrometers. The particle size and particle size distribution of the dielectric particles is selected so as to impart the desired degree of rms roughness to the non-conductive surface..

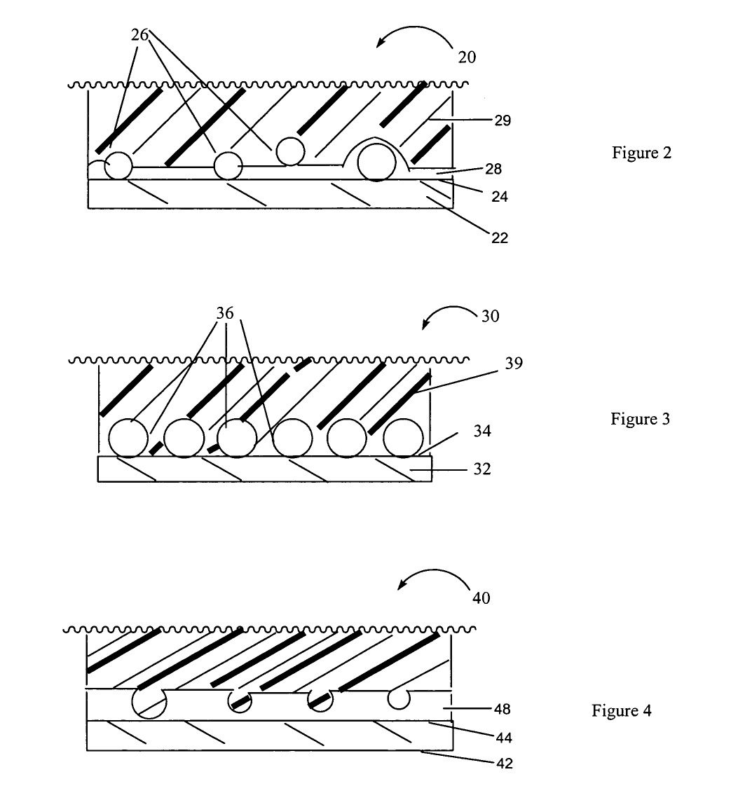

The dielectric particles or agglomerates can be adhered to a surface of the conductive layer by a variety of different methods, provided that the method does not substantially increase the surface roughness of said conductive layer. For example, the organic or inorganic dielectric particles can be bonded to the surface using an adhesive, as shown in FIG. 2. In FIG. 2, circuit material 20 comprises a conductive layer 22, preferably a copper conductive layer having a smooth surface 24. Dielectric particles 26 are disposed on surface 24, adhered thereto using adhesive 28. The dielectric particles can be covered by adhesive or embedded in adhesive 26. The particles provide enhanced adhesion between surface 24 and dielectric substrate 29. In an embodiment, the particles and adhesive cover the surface of the conductive layer without gaps or discontinuities.

The adhesive can be a high temperature thermoset or thermoplastic thin film adhesive. A variety of high temperature thermoset or thermoplastic materials that provide adequate adhesion to both the smooth conductive surface and the dielectric particles can be used, for example epoxies, polyimides, silicones, polyamides, polyarylene ethers, cyanurates, polybenzoxazines, polybenzoxazoles, polybenzimidizoles, polyarylates, polyesters, polycarbonates, polyethers, polyurethanes, polysulfones, and copolymers and mixtures thereof. The adhesive must be sufficiently high temperature resistant to withstand the subsequent lamination of conductive layer to the dielectric substrate. The conductive surface can be treated with an adhesion-promoting agent such as an organoalkoxysilane or tetraalkoxysilane before applying the adhesive coating layer.

The organic or inorganic dielectric particles can also be bonded to the conductive surface using crosslinking organoalkoxysilanes, for example silanes of the formula (R¹O)₄₋ₓSiRₓ wherein x is 0-3, R¹ is a C₁₋₆ alkyl group, preferably methyl or ethyl, and R is a substituted or unsubstituted C₁₋₆ alkyl group. Such silanes can react with hydroxyl groups present on silica and copper surfaces. Where R is substituted with an organic functionality such as an amine, epoxy, methacrylate, or the like, the silane can react with functional groups in organic particles and hydroxyl groups on the copper surface. In one embodiment the adhesive comprises a mixture of an organoalkoxysilane (wherein x=1−3) and tetraalkoxysilane (wherein x=0) such as tetramethyl- or tetraethylalkoxysilane. Appropriate selection of the type and amount of organoalkoxysilane and tetraalkoxysilane allows adjustment of the flexibility of the coating and level of adhesion to the conductive surface. This type of adhesive layer is particularly advantageous if a silica or silicate particle is used as the non-conductive roughening material.

The adhesive can be applied to the conductive surface by methods known in the art, for example spraying, powder coating, dipping, coating, spin coating, solution casting, and the like. The dielectric particles can be applied to the conductive layer prior to application with the adhesive, incorporated into the adhesive, or applied to the conductive layer after the adhesive is deposited. For example, the dielectric particles can be applied to a layer of the uncured (in the case of a thermoset coating) or melted (in the case of a thermoplastic coating) adhesive disposed on the conductive surface, and then adhered when the coating cures or solidifies.

The adhesive layer need not be organic. A layer of the particles disposed on the conductive surfaced can be bonded to the surface by heating the conductive metal in a reactive atmosphere to form a thin layer of a metal-metal oxide eutectic melt. The metal-metal oxide eutectic compound has a melting point lower than the metal and is also capable of wetting a particulate material. The formation of such a layer on a conductive surface could provide an adhesive layer for the particulate material. One description of this process using a copper-copper oxide eutectic is set forth in U.S. Pat. No. 3,993,411 to Babcock et al.

Alternatively, the particles can be applied directly to the surface of the conductive layer as shown in FIG. 3, wherein circuit material 30 comprises a conductive layer 32 and conductive dielectric particles 36 adhered thereto, providing increased adhesion of dielectric layer 39. While not shown in the Figure, it is preferred that the particles cover the surface of the conductive layer without gaps or discontinuities. The particles can be plasma coated, sputtered, thermally sprayed, or otherwise applied directly to the surface of the conductive layer. In another embodiment, uncured thermoset particles can be applied in a liquid or deformable solid form directly to the surface of the conductive layer in the form of individual droplets, rather than as a continuous film. The isolated thermoset particles themselves provide for the roughness necessary to enhance the mechanical bond with the resin of the dielectric substrate. The thermoset particles can be formed like “mushrooms” with the base adhering to the copper foil and the “caps” providing an additional mechanical interlocking with the resin to increase adhesion.

In still another embodiment, as shown in FIG. 4 at 40, the adhesive film layer 48 itself can be used to provide the non-conductive surface roughness. This roughness can be imparted by disposing adhesive layer 48 onto surface 44 of conductive layer 42, printing the uncured thermoset adhesive in the selected pattern, and then curing the adhesive. For example, uncured thermoset adhesive layer 48 can be holographically embossed prior to curing. An uncured thermoset or softened thermoplastic film can also be mechanically embossed to form the non-conductive roughened layer. The roughness can alternatively be formed directly in the cured polymeric adhesive layer by a physical subtractive method such as sanding, grinding, rotogravure, or laser machining. The roughness can also be formed by a chemically subtractive method such as etching.

The adhesive can comprise other additives known in the art, for example an antioxidant, a cross-linking agent, a cross-linking accelerator, a thermal stabilizer, a thickener, a plasticizer, a tackifier, a toughener, a moisture stabilizer, a curing inhibitor, a storage stabilizer, a colorant, and/or a nanoparticulate dielectric filler. While such dielectric fillers are not expected to significantly affect the roughness of the surface, they can be used to adjust the dielectric constant, the viscosity, and other properties of the adhesive material. In this or any other embodiment the surface of the conductive layer can be further treated to enhance adhesion of the roughened dielectric layer, e.g., plasma or silane treated.

In still another embodiment, a non-conductive roughness is imparted to the conductive surface by foaming a thermoset or thermoplastic polymeric layer onto the smooth conductive layer. In this embodiment the dielectric substrate resin fills the pores of the foam during lamination of the foil to the circuit substrate. The foamed polymeric layer can be achieved by mechanical frothing, chemical blowing agents, or fugitive fillers that are subsequently removed by chemical treatment, solvents, or heat. It is preferred that the pores not penetrate to the surface of the conductive layer.

In one embodiment the adhesive comprises a pore-forming agent that is selectively removed after deposition on the conductive surface. The pore-forming agent can be any organic or inorganic substance that can be dispersed in the adhesive layer and then is removable to form the desired roughened surface. Removal can be by evaporation, dissolution, selective abrasion, chemical treatment, and the like. Systems suitable for the formation of porous organic adhesives include thermoplastic polymers such as polyolefins (e.g., polyethylenes), polyesters, polyamides, polystyrene, polycarbonate, polyvinyl chloride and polysulfones and pore forming agents such as plasticizers (e.g., petroleum oil, polyethylene glycol, polypropylene glycol, glycerol, phthalic acid esters and fatty acid esters) and salts, which are removable by washing or extraction. The size of the pores and their surface area can be controlled by the amount and nature of the pore-forming agent.

Non-conductive roughness can also be imparted using radiation-curable coatings such as ultraviolet (UV)-curable coatings, electron-beam-curable coatings, microwave-curable coatings, and the like. In this embodiment, a layer of a radiation-curable coating is disposed onto a smooth conductive layer. A mask that is impenetrable by radiation effective to cure the radiation-curable coating patterned to allow selective penetration of the radiation in the desired roughness pattern. The mask is placed on the radiation-curable coating, and the combination of the radiation-curable coating and the mask are exposed to said radiation. After curing is effected, the mask is removed, and the uncured portion of the radiation-curable coating is removed, for example by washing the coating with a solvent effect to remove the uncured portion of the coating but leave the cured portions. Radiation-curable organic thermosetting materials can be used, or inorganic materials, such as certain UV-curable preceramic silicon or siloxane-containing materials.

The porosity can also be achieved by exposing certain polymeric layers to an oxidizing atmosphere.

The thickness of the roughened dielectric layer will depend on the type of layer used and the materials used to form it. In general the layer will be thick enough to cover the desired portion of the conductive layer without discontinuities and provide the desired roughness, without significantly increasing the overall thickness of the circuit material. Suitable thicknesses include, for example about 10 micrometers or less, more specifically about 5 micrometers or less. Other thicknesses can be used.

The terms “first,” “second,” and the like herein do not denote any order, quantity, or importance, but rather are used to distinguish one element from another. The singular forms “a,” “an,” and “the” include plural referents unless the context clearly dictates otherwise. “Adhered” and “bonded” are used interchangeably herein, and include adhesion and/or bonding with or with a separate adhesive. All references are incorporated herein by reference. The endpoints of all ranges reciting the same characteristic are combinable and inclusive of the recited endpoint.

While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

What is claimed is:

1. A method for the manufacture of a circuit material, comprising
forming a roughened, non-conductive surface on the surface of a conductive layer; and
bonding a dielectric layer onto the roughened, non-conductive surface using heat and pressure.

2. The method of claim 1, wherein the roughened surface provides enhanced adhesion between the conductive surface and the dielectric layer compared to the same conductive surface and dielectric layer without the surface roughening.

3. The method of claim 1, wherein the roughened, non-conductive surface has an rms roughness of about 0.5 micrometers or greater.

4. The method of claim 3, wherein the roughened, non-conductive surface has an rms roughness of about 1.0 micrometers or greater.

5. The method of claim 4, wherein the roughened, non-conductive surface has an rms roughness of about 2 to about 4 micrometers.

6. The method of claim 1, wherein the surface of the conductive layer has an rms roughness of less than about 0.5 micrometers.

7. The method of claim 6, wherein the surface of the conductive layer has an rms roughness of less than about 0.2 micrometers.

8. The method of claim 1, wherein the surface of the conductive layer has an rms roughness of less than about 0.2 micrometers, and the roughened, non-conductive surface has an rms roughness of greater than about 0.5 micrometers.

9. The method of claim 1, wherein the conductive layer is copper.

10. The method of claim 1, wherein forming the roughened surface comprises adhering dielectric particles to the surface of the conductive layer.

11. The method of claim 1, wherein the dielectric particles have a median longest dimension of about 1 micrometer or more.

12. The method of claim 10, wherein the dielectric particles are inorganic.

13. The method of claim 10, wherein the dielectric particles are adhered by a thermoset or thermoplastic adhesive.

14. The method of claim 10, wherein the dielectric particles are adhered by a silane.

15. The method of claim 10, wherein the dielectric particles comprise metal oxide particles that are adhered by a eutectic melt of the metal foil and the metal oxide.

16. The method of claim 1, wherein forming the roughened surface comprises bonding a dielectric layer to the surface of the conductive layer, and patterning the surface of the dielectric layer.

17. The method of claim 16, wherein patterning is by printing, rotogravure, abrading, mechanical embossing, laser machining, and/or etching.

18. The method of claim 1, wherein forming the roughened surface comprises plasma deposition, powder deposition, thermal spray, chemical vapor deposition, and the like.

19. The method of claim 1, wherein forming the roughened surface comprises adhering a porous dielectric layer to the surface of the conductive layer.

20. The method of claim 19, wherein the porous dielectric layer is formed by mechanical frothing, chemical blowing agents, or pore forming agents that are subsequently removed by chemical treatment, solvents, or heat.

21. The method of claim 20, wherein the pores are formed after bonding to the conductive layer.

22. The method of claim 1, wherein forming the roughened surface comprises patterning radiation-curable coatings.

23. A circuit material, comprising
a conductive layer having a first surface;
a dielectric substrate disposed on the first surface of the conductive layer; and
a roughened dielectric layer disposed between the first surface and the dielectric layer, thereby providing mechanical interlocking between the roughened dielectric layer and the dielectric substrate.

24. The circuit material of claim 23, wherein the roughened dielectric layer provides enhanced adhesion between the conductive surface and the dielectric layer compared to the same conductive surface and dielectric layer without the surface roughening.

25. The circuit material of claim 23, wherein the surface of the conductive layer has an rms roughness of less than about 0.5.

26. The circuit material of claim 23, wherein the circuit layer is copper.

27. The circuit material of claim 23, wherein the roughened dielectric layer comprises particles on the surface of the conductive layer.

28. The circuit material of claim 23, wherein the roughened dielectric layer comprises a porous layer.

29. A circuit material formed by the method of claim 1.

30. A circuit comprising the circuit material of claim 23.
